(19) United States
(12) Patent Application Publication
(10) Pub. No.: US 2016/0073530 A1
(43) Pub. Date: Mar. 10, 2016

(54) DESIGN AND APPARATUS FOR A SEGMENTED DEVICE ENCLOSURE

(71) Applicant: Intel Corporation, Santa Clara, CA (US)

(72) Inventors: Keith Nolan, Mullingar (IE); Mark Kelly, Leixlip (IE); Hugh M. Carr, Delgany (IE); Gabriel Mullarkey, Chapelizod (IE)

(21) Appl. No.: 14/848,329

(22) Filed: Sep. 8, 2015

Related U.S. Application Data
(60) Provisional application No. 62/047,320, filed on Sep. 8, 2014.

(51) Int. Cl. H05K 7/00

(52) U.S. Cl. CPC H05K 7/005

(57) ABSTRACT

The present invention discloses a segmented device system. The segmented device system includes a plurality of modules. Each module incorporates a sub-system which provides a unique function (or set of functions). The segmented device includes a set of flexible interconnections which transfer power and data between adjacent modules. A segmented device consistent with the present disclosure can flex, bend, and wrap around a mounting structure. The segmented device allows for the expansion and rapid replacement of any segments. In addition, such extensibility and ability to shorten or contract the device enables the device to fit optimally on that which the device is mounted.

### CROSS-REFERENCE TO RELATED APPLICATIONS

This application claims the benefit of U.S. Provisional Application No. 62/047,320, filed Sep. 8, 2014.

### FIELD

This disclosure pertains to a segmented device and more particularly to a segmented system which include power, sensing, and communications sub-modules.

### BACKGROUND

Conventional externally-mounted devices are installed in enclosed systems (e.g., weather-proof boxes) which are often difficult to disguise when mounted to a fixture in a public area. In addition, the dimensions of the weather-proof units make it difficult to mount to various contours of various mounting surfaces.

During maintenance, a technician is required to remove the systems and replace the various defective parts. However, this may lead to other problems as some technicians may cause further damage by inadvertently tampering with other components during the maintenance process. A fixed-size enclosed system may limit the ability of a technician to adequately add new hardware and features. For example, the enclosed systems may include large battery power supplies and other units of various sizes and enclosure types making the enclosed systems difficult to mass produce from a single enclosure type.

Therefore, a need exists for a system that can be easily reconfigured and readily serviced without risking damage to each sub-module or unit. The present disclosure addresses this need.

### BRIEF DESCRIPTION OF THE FIGURES

To facilitate understanding, identical reference numerals have been used, where possible, to designate identical elements that are common to the drawings. The drawings are not necessarily to scale and the relative dimensions of various elements in the drawings are depicted schematically and not necessarily to scale. The techniques of the present disclosure may readily be understood by considering the following detailed description in conjunction with the accompanying drawings, in which:

FIG. 1A is a partial exploded view of a segmented device system.

FIG. 1B is a perspective view of a configured segmented device system of FIG. 1A.

FIG. 2 is a schematic view of a segmented device system with top-mounted interconnections.

FIG. 3 is a schematic view of the interconnection incorporated within the segmented device system displayed in FIG. 2.

FIG. 4 is a schematic view of the interconnection incorporated within the segmented device system displayed in FIGS. 1A-1B.

FIG. 5 is an exemplary illustration of a segmented device system mounted to a lamp post.

FIG. 6 is an exemplary illustration of a vehicle with a segmented device system coupled thereto.

### DETAILED DESCRIPTION

A detailed description of some embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to some embodiments have not been described in detail to avoid unnecessarily obscuring the description.

The present invention discloses a segmented device system. The segmented device system includes a plurality of modules. Each module incorporates a sub-system which provides a unique function (or set of functions). The segmented device includes a set of flexible interconnections which transfer power and data between adjacent modules. A segmented device consistent with the present disclosure can flex, bend, and wrap around a mounting structure. The segmented device allows for the expansion and rapid replacement of any segments. In addition, such extensibility and ability to shorten or contract the device enables the device to fit optimally on that which the device is mounted. A segmented device system may be incorporated within an internet of things system/network.

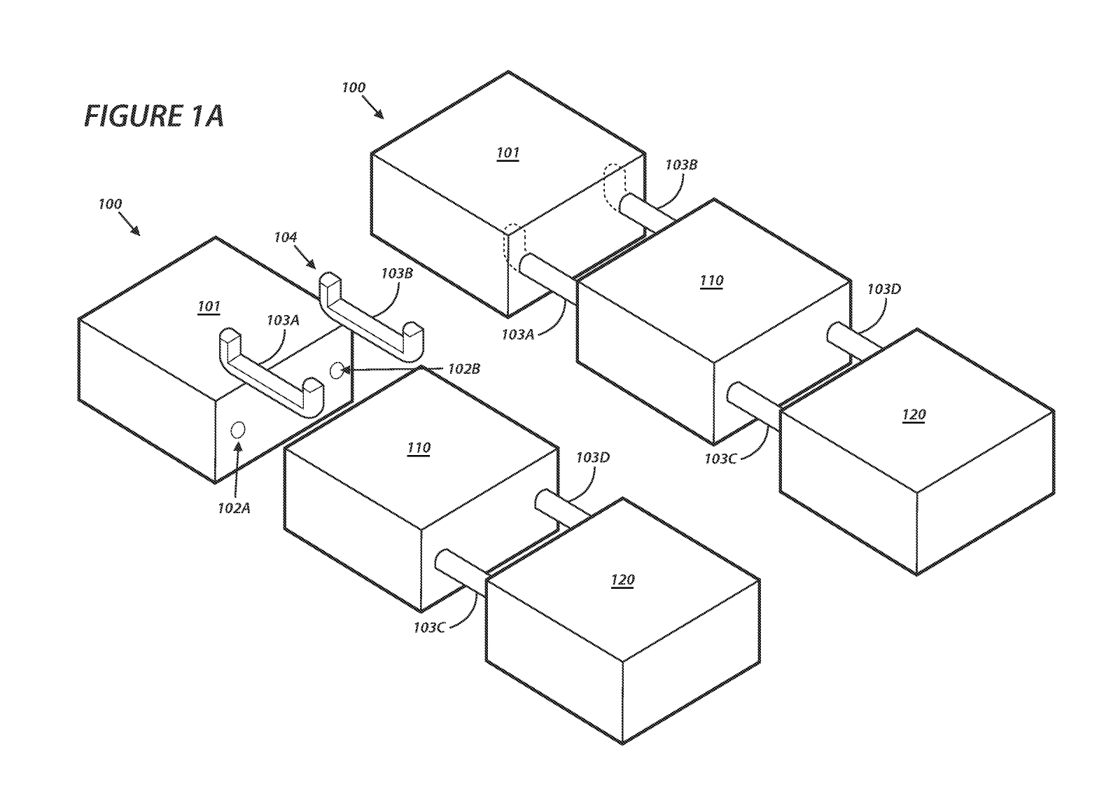

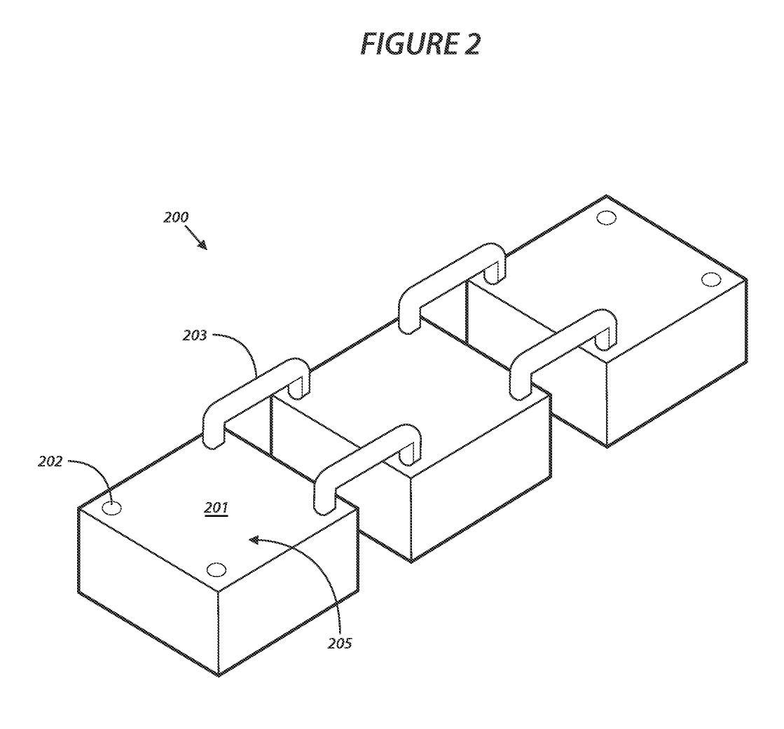

FIG. 1A is a partial exploded view of a segmented device system 100. System 100 includes two segments 101, 110, 120. It should be understood by one having ordinary skill in the art that system 100 may include more than three segments. In the embodiment shown, segment 101 is a power module 101, segment 110 is a communications module 110, and segment 120 is sensor module 120. The segments have an external housing which conceals the electronics and required circuitry which enable the segments to work.

The segments include at least one cavity through which interconnections are lodged there through. In the embodiment shown, cavities 102a, 102b are disposed on the side of the segments. For example, each segment within segmented device system 100 includes cavities 102a, 102b (along with others not provided with reference numbers) through which interconnections 103a, 103b, 103c, 103d (collectively interconnections 103) are lodged there through to couple adjacent segments of system 100.

Interconnections 103 may comprise ultraviolet-resistant, Kevlar-coated, and plastic conduits. In some embodiments, interconnections 103 may be flexible hollow conduits which serve as structural interconnections between the units. Interconnections 103 can bend without causing the interconnect to fail.

Most notably, interconnections 103 provide support for a common power and data communications rail between the segmented modules. For example, interconnection 103 may serve as a channel to transfer power (i.e. power rail), stemming from power module 101, whereas interconnection 103 may transfer communication data (i.e., communication rail).

Sensor module 101 detects any of a desired characteristic. For example, sensor module 101 may detect air quality, weather, traffic movement, cattle movement, pollution, trespassing, radiation levels, combustion of gases and pre-emptive fire conditions, noise detection, building vibration and other material conditions, fluid levels and variations, gas levels and leakages, payment processing, patient conditions, human vitals, micro-climate levels, soil moisture, storage conditions, fleet route deviation, light intensity, or temperature. It should be understood that the present disclosure is not limited to the aforementioned list.

Segmented device system 100 may also include one or more additional sensor modules 101. Advantageously, additional sensor modules 101 may be added or removed “on the fly” without disrupting or tampering with other components of the system 100. For example, system 100 may include a sensor module 101 that detects the amount of traffic congestion and another sensor module 101 that detects the air quality within an urban area.

FIG. 1B is a perspective view of a configured segmented device system 100 of FIG. 1A. As shown, the interconnections 103 are lodged within the sides of the segments. In one embodiment, segmented device system 100 includes a power module 101, communications module 110, and sensor module 120.

Power module 101 includes various electronics and circuitry to generate power to distribute throughout the segmented device system 100. In some embodiments, power module 101 includes an energy harvesting power unit such that as the segmented device system 100 is exposed, the power unit captures, converts, and stores energy from ambient power sources. For example, energy may be derived from solar power, wind sources, salinity gradients, and kinetic sources. In some embodiments, power module 101 includes a common connection and wiring interface to send and receive communications to other modules within the segmented device system 100.

Communications module 110 includes various electronics and circuitry to send, receive and coordinate communication throughout the segmented device system 100. For example, communications module 110 includes a receiver and a transmitter device. Communications module 110 may request information from power module 101 such as the present power state. Communications module 110 may also request information from sensor module 120. For example, communications module 110 may request the data collected by sensor module 120 within a specific time frame (e.g., last hour). Likewise, communications module 110 may output information (e.g., power status, collected data, etc.) to an external device or computer server. Communications module 110 may be programmed to output information or may be pinged from an external device (e.g., a request for present power status).

Sensor module 120 includes various electronics and circuitry to detect a present state, change in condition, etc. of a physical, chemical, electrical or other property. Power module 101 may also include a common connection and wiring interface to send and receive communications to other modules within segmented device system 100.

Each segment is physically separated from each other and may have its own enclosure and shielding which results in better electromagnetic and radio frequency shielding. Accordingly, each enclosure and shielding may be customized to suit each particular module (e.g., metal shielding for radio frequency emitters). For example, a segmented device system 100 for air monitoring may require air apertures (e.g., wind sensor module). In contrast, the other modules can be effectively sealed. In addition, the communications module 110 may require an aperture for an antenna whereas the other modules may be more effectively sealed.

It should be understood by one having ordinary skill in the art that segmented device system 100 may not be limited to comprising power, communications, and sensor modules 101, 110, 120. Segmented device system 100 may include one or more sensor modules 120 or one or more power modules according the system's 100 need. For example, segmented device system 100 may include a backup power module. In some embodiments, communications module 110, sensor module 120, and other non-power modules may have an independent power supply therein.

Moreover, segmented device system 100 may include dummy segments. Dummy segments may be used to separate modules within the system 100 further from each other. For example, a dummy segment may separate sensor module 120 from the communications module 110 to minimize radio frequency interference (RFI) or electromagnetic interference (EMI).

FIG. 2 is a schematic view of a segmented device system 200 with top-mounted Interconnections 203. Cavities 202 are disposed on a top surface 205 of the segment modules 201 through which interconnections 203 are lodged there through.

The segments shown in the figure are aligned in a linear fashion. However, the present disclosure is not limited thereto. In some embodiments, the segments 201 are aligned in a non-linear fashion. The segments 201 shown in FIG. 2 have a cuboid shape. In some embodiments, segments 201 have a length between 6 and 8 cm, a width between 6 and 7 cm, and a depth between 4 and 6 cm. The present disclosure is not limited to segments with a cuboid shape. Segments 201 may have any shape to best meet the functionality requirements of the segment. Moreover, segments 201 need not all share the same shape.

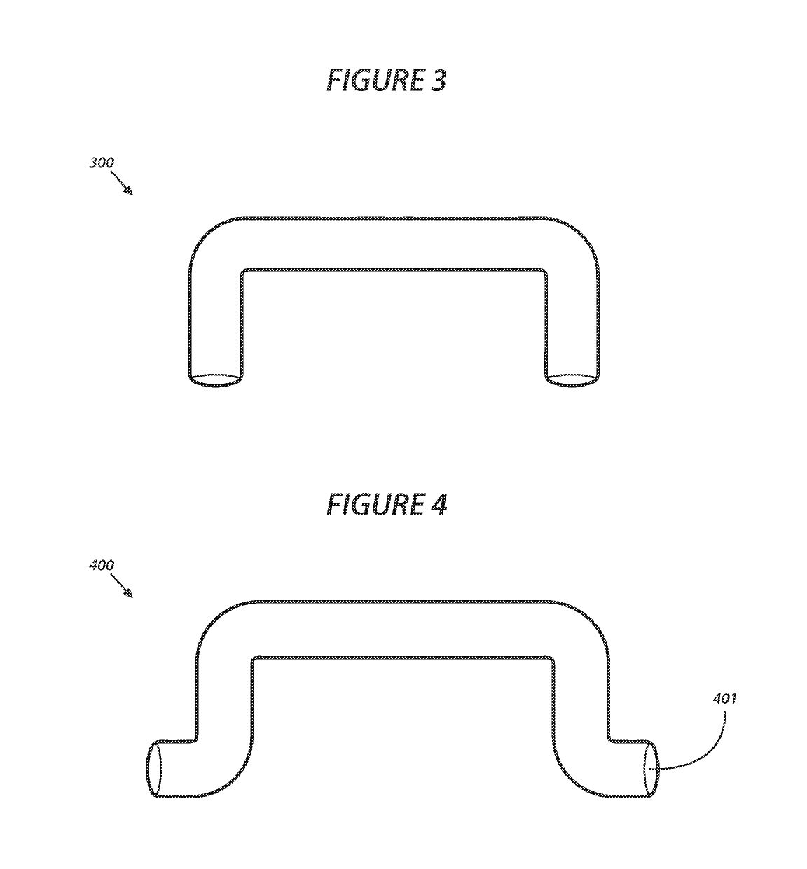

FIG. 3 is a schematic view of the interconnection 300 incorporated within the segmented device system displayed in FIG. 2. Interconnection 300 consists of a base region with arms extending in a perpendicular direction therefrom. Interconnection 300 provides a conduit (e.g., power or data) and a structural interconnection for a top-mounted enclosure configuration.

FIG. 4 is a schematic view of the interconnection 400 incorporated within the segmented device system displayed in FIGS. 1A-1B. Interconnection 400 provides a conduit (e.g., power or data) and a structural interconnection with improved anchoring features. In an embodiment, the improved anchoring features include hook portion 401 on end portions of the structure.

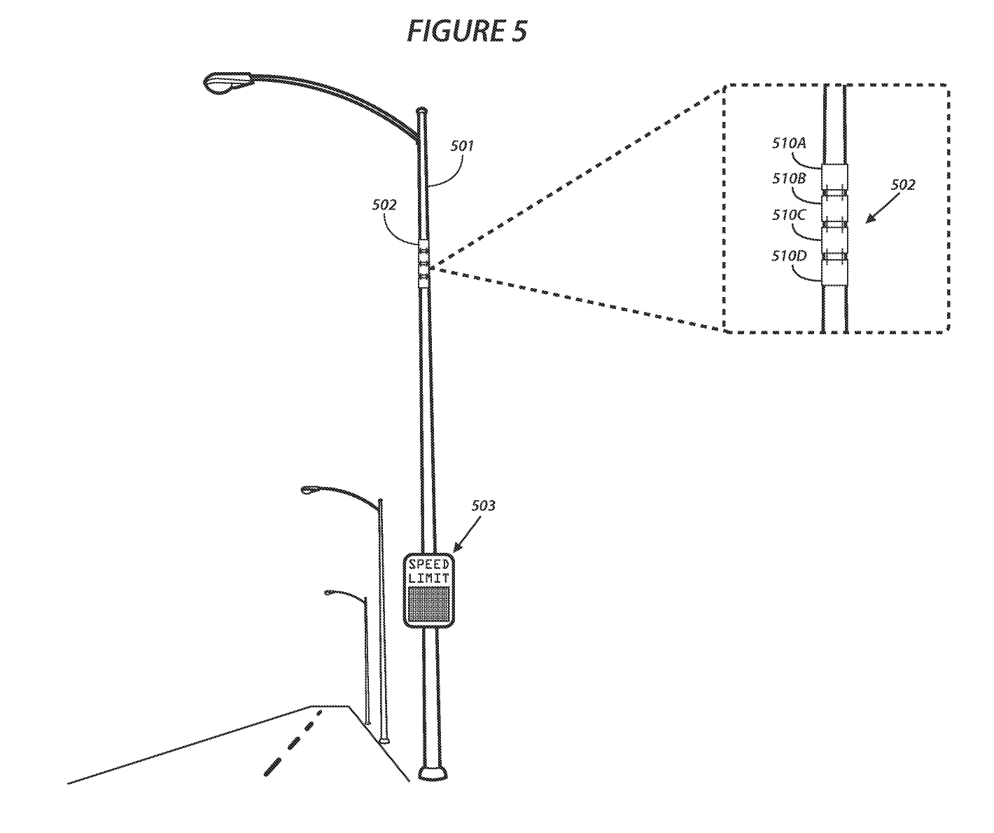

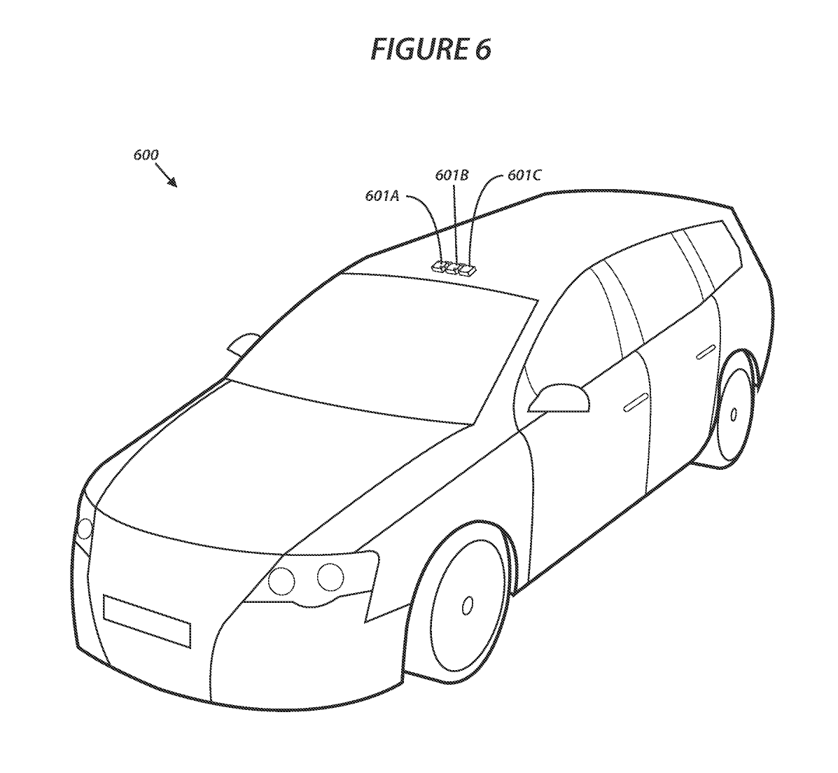

FIG. 5 is an exemplary illustration of a segmented device system 502 mounted to a lamp post 501. A segmented device system 502 consistent with the present disclosure may be mounted to various surfaces. Advantageously, the segmented device can accommodate many different contours of various surfaces.

Segmented device system 502 may be coupled to lamp post 501 by any suitable method known in the art. For example, system 502 may be coupled to lamp post 501 via a magnet, adhesive material, clamp assembly, or snap connection. In one embodiment, system 502 is coupled to lamp post 501 via a set of magnets. Although system 502 is mounted vertically on the lamp post 501, the present disclosure is not limited thereto. System 501 may also be mounted in a horizontal fashion on lamp post 501 or any other mounting structure as well.

As shown, segmented device system 502 includes four segment modules 510a, 510b, 510c, 510d (collectively segment modules 510) which are directed to power (power module 510a), communications (communications module 510b), and sensor detection (sensor modules 510c, 510d). Sensor modules 510c, 510d detect weather (e.g., temperature, rain, snow, etc.) and traffic conditions (e.g., vehicle speed, presence, etc.). The collected data from the sensors may be transmitted to the communications module 510b which may be further transmitted to an external device or system.

Based on the detected data by sensor modules 510c, 510d, the communications module 510b of the segmented device system 502 may communicate via a signal to an electronic road sign 503. For example, if the weather conditions are great (e.g., sunny), a higher speed limit may be displayed by the road sign 503. Alternatively, for poor weather conditions, communications module 510b may transmit another signal for the road sign to display a lower speed.

FIG. 6 is an exemplary illustration of a vehicle 600 with a segmented device system 601 coupled thereto. Segmented device system 601 has a plurality of modules—power module 601, communications module 602, and sensor module 603. Sensor module 603 may output location data or any data associated with vehicle 600. This data may be transmitted to an external device or computer server.

The present disclosure provides a description of a novel segmented device. It will be understood by those having ordinary skill in the art that the present disclosure may be embodied in other specific forms without departing from the spirit and scope of the disclosure disclosed. In addition, the examples and embodiments described herein are in all respects illustrative and not restrictive. Those skilled in the art of the present disclosure will recognize that other embodiments using the concepts described herein are also possible.

What is claimed is:

1. A segmented device, comprising:
a plurality of modules wherein each module is to perform a unique functionality;
wherein adjacent modules are coupled to each other by a set of flexible interconnections which transfer power and data there between.

2. The segmented device of claim 1, wherein the plurality of modules include at least one of a communications module, power module, or sensor module.

3. The segmented device of claim 1, wherein each flexible interconnection can bend without causing the interconnect to fail.

4. The segmented device of claim 1, wherein each flexible interconnection comprises ultraviolet-resistant, Kevlar-coated, and plastic conduits.

5. The segmented device of claim 1, wherein each flexible interconnection includes a pair of hook portions.

6. The segmented device of claim 5, wherein the flexible interconnections are disposed on a side portion of the modules.

7. The segmented device of claim 1, wherein the flexible interconnections are disposed on a top surface of the modules.

8. The segmented device of claim 1, wherein the plurality of modules are aligned in a non-linear fashion.

9. The segmented device of claim 1, wherein each module has a cuboid shape.

10. The segmented device of claim 9, wherein each module has a length between 6 and 8 cm, a width between 6 and 7 cm, and a depth between 4 and 6 cm.

11. The segmented device of claim 1, wherein the set of flexible interconnections includes at least a power rail and a data rail.

12. A system, comprising:
a segmented unit, comprising:
a communications module;
a power module;
a fist sensor module; and
a set of flexible interconnections between each adjacent module; and
a coupling means to attach the segmented unit to a mounting structure.

13. The system of claim 12, wherein each module comprises a housing.

14. The system of claim 12 further comprising a second sensor module wherein the first sensor module detects a first property whereas the second sensor module detects a second property.

15. The system of claim 12, wherein the first sensor module detects at least one of air quality, weather, traffic movement, cattle movement, pollution, trespassing, radiation levels, combustion of gases and pre-emptive fire conditions, noise detection, building vibration and other material conditions, fluid levels and variations, gas levels and leakages, payment processing, patient conditions, human vitals, micro-climate levels, soil moisture, storage conditions, fleet route deviation, light intensity, and temperature.

16. The system of claim 12, wherein the coupling means includes at least one of a magnet, an adhesive, clamp assembly, or snap connection.

17. The system of claim 12, wherein the communications module, power module, and first sensor module comprise a common connection and wiring interface.

18. The system of claim 12, wherein the power module includes an energy harvesting power unit.

19. The system of claim 12, wherein the segmented unit includes at least one dummy segment to separate the first sensor module from the communications module to minimize radio frequency interference or electromagnetic interference.

20. The system of claim 12, wherein the communications module comprises a receiver and a transmitter device.
